(19) United States
(12) Patent Application Publication
(10) Pub. No.: US 2020/0025834 A1
(43) Pub. Date: Jan. 23, 2020

(54) POWER SUPPLY DEVICE, POWER SUPPLY CONTROL METHOD, AND STORAGE DEVICE

(71) Applicant: TOSHIBA MEMORY CORPORATION, Minato-ku (JP)

(72) Inventor: Wataru OKAMOTO, Kamakura (JP)

(73) Assignee: TOSHIBA MEMORY CORPORATION, Minato-ku (JP)

(21) Appl. No.: 16/265,270

(22) Filed: Feb. 1, 2019

(30) Foreign Application Priority Data
Jul. 17, 2018 (JP) 2018-134397

(51) Int. Cl. G01R 31/40; G11C 16/30; G11C 16/10; G06F 1/30; G01R 19/165; G01K 1/14

(52) U.S. Cl. CPC G01R 31/40; G11C 16/30; G11C 16/10; G11C 16/0483; G01R 19/16552; G01K 1/14; G06F 1/30

(57) ABSTRACT

According to one embodiment, a power supply device includes a power supply circuit including circuit blocks and configured to generate power supply voltages based on an external power supply, detectors that detect failures of the circuit blocks, a nonvolatile memory, and a controller that stops an operation of the power supply circuit when any of the detectors detects the failure of any of the circuit blocks, and writes failure information of the power supply circuit into the nonvolatile memory. The failure information includes information indicating a type of the failure which has occurred and a circuit block among the circuit blocks in which the failure has occurred.

### CROSS-REFERENCE TO RELATED APPLICATIONS

This application is based upon and claims the benefit of priority from Japanese Patent Application No. 2018-134397, filed Jul. 17, 2018, the entire contents of which are incorporated herein by reference.

### FIELD

Embodiments described herein relate generally to a power supply device, a power supply control method, and a storage device.

### BACKGROUND

An electronic device includes a plurality of semiconductor devices (hereinafter simply referred to as devices). Since a power supply voltage for driving a device varies from device to device, the electronic device needs a power supply device for generating a plurality of power supply voltages for each device from an external power supply. A part of operation of generating the power supply voltages by the power supply device is controlled by a controller provided in the electronic device.

The electronic device sometimes does not normally operate due to a software-related failure (hereinafter referred to as a software failure). The software failure includes an event that the communication between the controller and the device has failed, or that the controller has accessed an error area of the device (for example, flash memory) in the electronic device. Therefore, when the software failure is detected, the electronic device is shut down. Before the shutdown, the electronic device writes software failure information indicating an occurrence point of the software failure and the like into the nonvolatile memory of the electronic device.

The electronic device that has been shut down due to occurrence of the software failure may sometimes be collected by a manufacturer. At the manufacturer side, the software failure information is read from the nonvolatile memory mounted on the collected device to perform failure analysis for identifying cause or the like of the software failure. The analysis result is fed back to a design section of the electronic device, thereby improving reliability of the electronic device.

The failure information written in the nonvolatile memory in the conventional electronic device is limited to the software failure information, and hardware failure information on a hardware-related failure (hereinafter referred to as hardware failure) of the controller and the power supply device is not written into the nonvolatile memory. In order to analyze the hardware failure of the controller and the power supply device, it is necessary to measure voltage and current of each part of the electronic device with a digital multi-meter or the like and to observe waveform of each part with an oscilloscope. These take time and also the work to identify the cause of the failure from the measurement result takes time, and thus the analysis efficiency is extremely poor.

### BRIEF DESCRIPTION OF THE DRAWINGS

FIG. 1 is a block diagram showing a configuration of an example of an information processing system including an SSD including a power supply device according to an embodiment.

FIG. 2 is a plan view showing an example of a structure of the SSD.

FIG. 3 is a block diagram showing an example of a configuration of the SSD including the power supply device according to the embodiment.

FIG. 4 is a diagram showing an example of failure information in the embodiment.

FIG. 5 is a flowchart showing an example of an operation of the power supply device according to the embodiment.

### DETAILED DESCRIPTION

Hereinafter, an embodiment will be described with reference to the drawings. Note that the disclosure is merely an example, and the invention is not limited by the contents described in the following embodiment. Naturally, the modifications easily conceivable by those skilled in the art are included in the scope of the disclosure. In order to make the description clearer, there may be cases where the size, shape, etc., of each part are schematically represented by changing them relative to the actual embodiment in the drawings. In the drawings, corresponding elements are denoted by the same reference numerals, and a detailed explanation may be omitted.

A power supply device according to the embodiment can be applied to any electronic device. As a first embodiment, an example applied to a memory system (solid-state drive, abbreviated as SSD) using a nonvolatile semiconductor memory, such as a flash memory, will be described.

In general, according to one embodiment, a power supply device comprises a power supply circuit comprising circuit blocks and configured to generate power supply voltages based on an external power supply, detectors that detect failures of the circuit blocks, a nonvolatile memory, and a controller that stops an operation of the power supply circuit when any of the detectors detects the failure of any of the circuit blocks, and writes failure information of the power supply circuit into the nonvolatile memory. The failure information comprises information indicating a type of the failure which has occurred and a circuit block among the circuit blocks in which the failure has occurred.

[Configuration of Information Processing System]

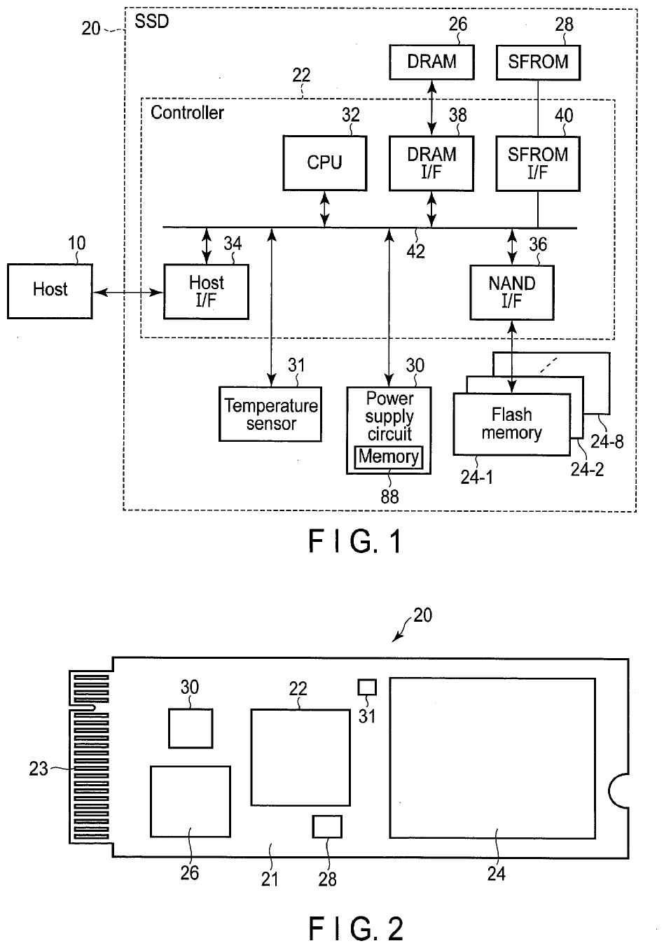

FIG. 1 is a block diagram showing a configuration of an example of an information processing system including an SSD. The system includes a host device (hereinafter referred to as a host) 10 and an SSD 20. The SSD 20 is a semiconductor storage device configured to write data into the nonvolatile semiconductor memory and to read data from the nonvolatile semiconductor memory.

The host 10 accesses the SSD 20, writes data into the SSD 20, or reads data from the SSD 20. The host 10 may be a server (also referred to as a storage server) that stores a large amount of various data into the SSD 20, or may be a personal computer. The SSD 20 can be used as a main storage of the host 10. The SSD 20 may be built in a housing of the host 10 or may be connected to the host 10 via a cable or a network.

The SSD 20 includes a controller 22, a flash memory 24 as a nonvolatile semiconductor memory, a DRAM 26, an SFROM (serial flash ROM) 28, a power supply circuit 30, a temperature sensor 31, and the like. The controller 22 includes a CPU 32, a host interface (I/F) 34 for electrically interconnecting the host 10 and the SSD 20, a NAND interface (I/F) 36, a DRAM interface (I/F) 38, an SFROM interface (I/F) 40, and the like. The CPU 32, the host I/F 34, the NAND I/F 36, the DRAM I/F 38, and the SFROM I/F 40 can be connected to a bus line 42. The controller 22 may be realized by a circuit such as System-on-chip (SoC), ASIC, FPGA, and the like.

As the host I/F 34, for example, standards such as, Small Computer System Interface (SCSI) (registered trademark), PCI Express (registered trademark) (also referred to as PCIe (registered trademark)), Serial Attached SCSI (SAS)(registered trademark), Serial Advanced Technology Attachment (SATA) (registered trademark), Non Volatile Memory Express (NVMe (registered trademark)), Universal Serial Bus (USB) (registered trademark), can be used, but it is not limited thereto.

The flash memory 24 is, for example, formed of a NAND type flash memory, but it is not limited to a NAND type flash memory, but another nonvolatile semiconductor memory may be used. The flash memory 24 may include a plurality of flash memory chips (or a plurality of flash memory dies). Here, eight flash memory chips 24-1, 24-2, . . . 24-8 are provided as an example. Each chip 24-1, 24-2, . . . 24-8 is realized as a flash memory configured to be capable of storing one bit or a plurality of bits per memory cell. The reading or writing of the flash memory 24 is controlled by the controller 22. The flash memory 24 is connected to the NAND I/F 36.

The DRAM 26, as a random access memory that is a volatile memory, may not be provided outside the controller 22, but a random access memory that is a volatile memory that can be accessed at higher speed such as SRAM may be incorporated in the controller 22. The random access memory such as the DRAM 26 may be provided with a write buffer which is a buffer area for temporarily storing data to be written into the flash memory 24, a read buffer which is a buffer area for temporarily storing data read from the flash memory 24, a cache area of a lookup table (referred to as an LUT) that functions as an address translation table (also referred to as a logical address/physical address conversion table), and a storage area of system management information, such as various values and various tables used during processing of the SSD 20. The LUT manages mapping between each logical address and each physical address of the flash memory 24. The DRAM 26 is connected to the DRAM I/F 38.

The SFROM 28 is a nonvolatile programmable memory that is serially communicated with the controller 22 and stores failure information detected by the controller 22. The controller 22 communicates with other devices, such as the flash memory 24, the DRAM 26, the temperature sensor 31, etc., to transmit and receive data. The controller 22 detects a communication failure with the device. Alternatively, the controller 22 has accessed the error area of the device (for example, the flash memory 24). When the controller 22 detects the software failure described above, the controller 22 writes software failure information indicating what type of software failure has occurred in which device into the SFROM 28. The SFROM 28 is a flash memory, but it may be a one-time ROM (OTP-PROM) capable of writing once, or an electrically programmable/erasable ROM (EPPROM). The SFROM 28 is connected to the SFROM I/F 40. The SFROM 28 can store a plurality of items of software failure information.

While the controller 22 is in operation, the software failure information is written into the SFROM 28. When the controller 22 is not operating normally or when no power is supplied to the controller 22, it is impossible to write software failure information into the SFROM 28. However, as will be described later, hardware-related abnormal operations of the controller 22 and the power supply circuit 30 are detected by the power supply circuit 30, and hardware failure information indicating the detection result is written into a memory 88 by the power supply circuit 30. This enables failure analysis.

The power supply circuit 30 generates a plurality of internal power supply voltages necessary for each device of the SSD 20 from one or several external power supplies supplied from the host 10. In FIG. 1, a power supply line is not shown. The power supply circuit 30 may be a single or several ICs. The control signal for controlling the power supply circuit 30 is supplied from the controller 22 according to the serial communication standard, for example, I2C (Inter-Integrated Circuit) standard. The temperature data of the SSD 20 measured by the temperature sensor 31 is supplied to the controller 22 according to the serial communication standard, for example, I2C standard. The controller 22 adjusts the control signal to the power supply circuit 30 so that the voltage generated by the power supply circuit 30 changes according to the temperature of the SSD 20 measured by the temperature sensor 31.

[Appearance of SSD]

FIG. 2 is a plan view showing an example of the appearance of the SSD 20. The SSD 20 is provided with a substrate 21 for mounting components. The substrate 21 has a substantially rectangular shape. In recent years, as a standard of the substrate 21, there is the M.2 standard defined for the form factor and connection terminal of the built-in expansion card of the computer. The M.2 standard proposes various sizes and includes very small types such as 22 mm×42 mm, 22 mm×60 mm, 22 mm×80 mm, for example. As the SSD 20 is miniaturized, the flash memory 24 is also downsized. A temperature of the downsized flash memory 24 sometimes becomes high during operation. The controller 22, the flash memory 24, the DRAM 26, the SFROM 28, the power supply circuit 30, and the temperature sensor 31, which are circuit components each formed into an IC, are mounted on the substrate 21. The temperature sensor 31 measures the temperature near the flash memory 24. A connector 23 that is electrically connected to the host 10 is provided at a side end on one short side of the substrate 21. A particular wiring pattern (not shown) formed on the substrate 21 is electrically connected to a particular terminal pin of the connector 23 and a particular terminal of the controller 22.

[Electrical Configuration of SSD]

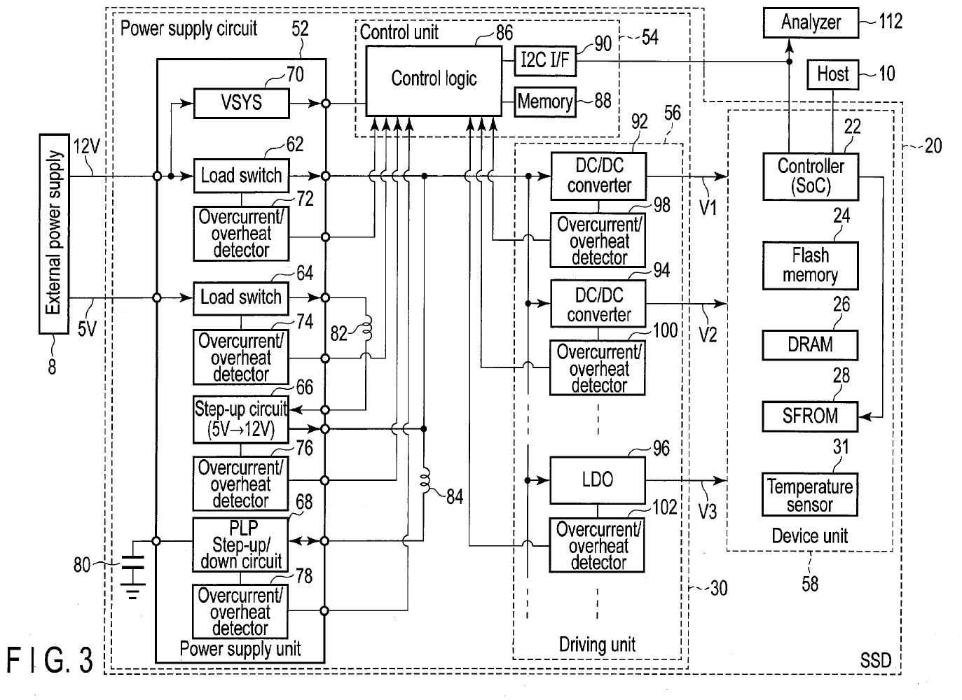

FIG. 3 is a detailed block diagram of the SSD 20 for showing details of an example of the power supply circuit 30. The power supply circuit 30 includes a power supply unit 52, a control unit 54, and a driving unit 56. Two external power supply DC voltages of 12V and 5V are applied to the power supply unit 52 from an external power supply 8. The host 10 may also serve as the external power supply 8. The number of external power supply voltages is not limited to two and may be only one (DC voltage of 12V) or three or more. The values of the external power supply voltages are not limited to the above examples, and other values may be used.

The power supply unit 52 includes a plurality of blocks, such as the load switches 62 and 64, the step-up circuit 66, and the PLP step-up/down circuit 68. The power supply unit 52 may be a single IC. An external power supply voltage (voltage signal) of 12V from the external power supply 8 is applied to the load switch 62. An external power supply voltage (voltage signal) of 5V from the external power supply 8 is applied to the load switch 64. The load switches 62 and 64 are switches for turning on/off the current, which are on during normal operation. When the load switches 62 and 64 are on, a current flows between the respective input and output and a voltage signal equal to the input voltage is output. When a current equal to or greater than a particular value (current higher than expected: overcurrent) flows, the load switches 62 and 64 are turned off and the output voltage becomes 0V.

A voltage signal of 12V output from the load switch 62 is applied to the driving unit 56. A voltage signal of 5V output from the load switch 64 is applied to the input terminal of the step-up circuit 66 via an inductor 82. When a voltage signal of 5V is applied to the power supply circuit 30 from the external power supply 8 and a voltage signal of 5V from the load switch 64 is applied to the step-up circuit 66, the step-up circuit 66 steps up the input voltage of 5V to 12V and outputs the step-up voltage signal of 12V from the output terminal. When a voltage signal of 5V is not applied to the power supply circuit 30 from the external power supply 8 and a voltage signal of 5V from the load switch 64 is not applied to the step-up circuit 66, the output voltage of the step-up circuit 66 becomes 0V.

The load switch 62 and the step-up circuit 66 both as a 12V power supply are connected in parallel to the input terminal of the driving unit 56. The voltage signal of 12V output from the load switch 62 and the voltage signal of 12V output from the step-up circuit 66 are applied to the driving unit 56. The voltage signal of 12V output from the step-up circuit 66 is applied to the input/output terminal of a PLP (Power Loss Protection) step-up/down circuit 68 via an inductor 84. When the voltage signal of 12V and the voltage signal of 5V both from the external power supply 8 are applied to the power supply circuit 30, and when the voltage signal of 12V from the load switch 62 and the voltage signal of 12V from the step-up circuit 66 are applied to the input/output terminal of the PLP step-up/down circuit 68 via the inductor 84, the PLP step-up/down circuit 68 steps up the input voltage signal of 12V from the inductor 84 and charges a PLP capacitor 80 with the step-up voltage. When the voltage signal of 12V and the voltage signal of 5V both from the external power supply 8 are not applied to the power supply circuit 30, and when the voltage signal of 12V from the load switch 62 and the voltage signal of 12V from the step-up circuit 66 are not applied to the input/output terminal of the PLP step-up/down circuit 68, the output voltage of the PLP step-up/down circuit 68 becomes 0V.

The reason why two external power supply voltages are provided is that the power that can be consumed differs depending on the power supply voltage, that is, the power that can be consumed from the 12V power supply differs from the power that can be consumed from the 5V power supply. Therefore, an external power supply of 5V is also provided in addition to the external power supply of 12V, and 5V is stepped up to 12V by the step-up circuit 66.

When the external power supply 8 is not connected to the power supply circuit 30, a voltage signal of 12V is not applied to the input/output terminal of the PLP step-up/down circuit 68. When the voltage signal of 12V is not applied, the PLP step-up/down circuit 68 steps down the charging voltage of the PLP capacitor 80 for a particular period and outputs a voltage signal of 12V to the inductor 84 via the input/output terminal. The PLP step-up/down circuit 68 is connected to the input terminal of the driving unit 56 in parallel to the step-up circuit 66 and the load switch 62. A voltage signal of 12V output from the PLP step-up/down circuit 68 is applied to the driving unit 56 via the inductor 84. When the external power supply 8 is not connected to the power supply circuit 30, no voltage signal of 12V is output from the load switch 62 and the step-up circuit 66.

That is, while the external power supply 8 is connected to the power supply circuit 30 and the power supply unit 52 operates normally, the voltage signal of 12V output from the load switch 62 and the voltage signal of 12V output from the step-up circuit 66 are applied to the driving unit 56. While the external power supply 8 is not connected to the power supply circuit 30 or the power supply unit 52 does not operate normally, the voltage signal of 12V output from the PLP step-up/down circuit 68 to the inductor 84 is applied to the driving unit 56. The voltage signal of 12V is output from the PLP step-up/down circuit 68 for a limited period (for example, several tens milliseconds) until the charged electric charge of the PLP capacitor 80 is discharged. Therefore, the voltage signal of 12V is applied to the driving unit 56 for a particular period since the power supply unit 52 fails to operate normally or since the external power supply 8 is disconnected from the power supply circuit 30, and then the driving unit 56 is operable.

The power supply unit 52 also includes a system power supply (VSYS) 70 for generating a system power supply voltage from the voltage signal of 12V. The system power supply voltage is applied to the control logic 86. As a result, even while the load switches 62 and 64, the step-up circuit 66, and the PLP step-up/down circuit 68 do not output the voltage signals, the control logic 86 can operate as long as the external power supply 8 is connected to the power supply circuit 30.

The driving unit 56 generates a plurality of internal power supply voltages V1, V2, V3, . . . from the voltage signal of 12V output from the power supply unit 52 and supplies them to a device unit 58 included in the SSD 20. The device unit 58 includes a plurality of blocks, such as the controller 22 (SoC), the flash memory 24, the DRAM 26, the SFROM 28, and the temperature sensor 31. The voltage signal of 12V output from the load switch 62, the voltage signal of 12V output from the step-up circuit 66, and the voltage signal of 12V output from the PLP step-up/down circuit 68 are applied to a plurality of DC/DC converters 92, 94, . . . and a plurality of LDOs (Low Dropout) 96, The internal power supply voltages V1, V2, V3, . . . are generated by the DC/DC converters 92, 94, . . . and the LDOs (Low Dropout) 96, . . . . For example, specific values of the internal power supply voltages are V1=1.5V, V2=0.7V, and the like.

The number of the DC/DC converters 92, 94, . . . and the LDOs 96, . . . in the driving unit 56 may be several times (for example, two to three times) the number of the devices of the device unit 58. In particular, the controller 22 may require different voltages for the CPU 32, the host I/F 34, the NAND I/F 36, the DRAM I/F 38, and the SFROM I/F 40 (see FIG. 1), and the number of the blocks in the driving unit 56 is larger than the number of devices in the device unit 58.

In general, the DC/DC converters 92, 94, . . . require a large current, and the LDOs 96, . . . operate with a small current. For example, the output voltage V3 of the LDO 96 is used as an analog power supply of the controller 22. The voltage value generated by any of the DC/DC converters 92, 94, . . . and the voltage value generated by any of the LDOs 96, . . . may be different, or may be the same. The driving unit 56 may be a single IC, or may be discrete elements. Some of the DC/DC converters 92, 94, . . . and the LDO 96, in the driving unit 56 may be provided in the power supply unit 52.

The driving unit 56 is operable for a particular period since the power supply unit 52 fails to operate normally or since the external power supply 8 is disconnected from the power supply circuit 30. During the particular period, the internal power supply voltages V1, V2, V3, . . . are applied to the device unit 58. During this time, the controller 22 saves unwritten data buffered in the DRAM 26 in the flash memory 24. After that, the SSD 20 may be shut down.

A hardware failure of the SSD 20 will be described. As an example, although the power supply circuit 30 normally operates, the device unit 58 of the SSD 20 may operate abnormally in some cases. For example, when at least one of the controller 22, the flash memory 24, the DRAM 26, the SFROM 28, the temperature sensor 31, etc., of the device unit 58 becomes overcurrent/overheat due to a hardware failure, at least one of the DC/DC converters 92, 94, . . . and LDOs 96, . . . of the driving unit 56 may become overcurrent/overheat in some cases. Therefore, by detection of overcurrent/overheat of the DC/DC converters 92, 94, . . . and the LDOs 96, . . . of the driving unit 56, abnormal operation of the device unit 58 of the SSD 20 can be detected.

As another example, although the device unit 58 of the SSD 20 operates normally, the power supply circuit 30 may operate abnormally in some cases. For example, at least any one of the load switches 62 and 64, the step-up circuit 66, and the PLP step-up/down circuit 68 of the power supply unit 52, the DC/DC converters 92, 94, . . . and the LDOs 96, . . . of the driving unit 56 may become overcurrent/overheat due to a hardware failure in some cases. Therefore, by detection of overcurrent/overheat of the load switches 62 and 64, the step-up circuit 66, the PLP step-up/down circuit 68, the DC/DC converters 92, 94, . . . and the LDOs 96, . . . , an abnormal operation of the power supply circuit 30 due to a hardware failure can be detected.

Therefore, in the power supply unit 52, overcurrent/overheat detectors 72, 74, 76, and 78 are connected to the load switches 62 and 64, the step-up circuit 66, and the PLP step-up/down circuit 68, respectively. The overcurrent/overheat detectors 72, 74, 76, and 78 detect an overcurrent when a current equal to or larger than a threshold value flows through each of the load switches 62 and 64, the step-up circuit 66, and the PLP step-up/down circuit 68. The overcurrent/overheat detectors 72, 74, 76, and 78 detect overheat when the temperature corresponding to the current flowing through each of the load switches 62 and 64, the step-up circuit 66, and the PLP step-up/down circuit 68 becomes equal to or more than a threshold value. The overcurrent/overheat detectors 72, 74, 76, and 78 each may include a temperature sensor, measure the temperatures of the load switches 62 and 64, the step-up circuit 66, and the PLP step-up/down circuit 68, and when the measured temperature becomes equal to or higher than a threshold value, may detect overheat. The overcurrent/overheat detectors 72, 74, 76, and 78, when having detected the overcurrent/overheat of the load switches 62 and 64, the step-up circuit 66, and the PLP step-up/down circuit 68, stop the operations of the load switches 62 and 64, the step-up circuit 66, and the PLP step-up/down circuit 68 and notify the control logic 86 of the detection result. Since the maximum allowable current and maximum allowable temperature may be different for each of the load switches 62 and 64, the step-up circuit 66, and the PLP step-up/down circuit 68, the overcurrent threshold value and the overheat threshold value of the overcurrent/overheat detectors 72, 74, 76, and 78 may be different. The detection result is hardware failure information indicating what type of hardware failure has occurred in which block. Failure includes overcurrent or overheat.

In the driving unit 56, overcurrent/overheat detectors 98, 100, 102, . . . are respectively connected to the DC/DC converters 92, 94, . . . and the LDOs 96, . . . . The overcurrent/overheat detectors 98, 100, 102, . . . , when having detected the overcurrent/overheat of the DC/DC converters 92, 94, . . . and the LDOs 96, . . . , stop the operations of the DC/DC converters 92, 94, . . . and the LDOs 96, . . . , and notify the control logic 86 of the detection result. Since the maximum allowable current and maximum allowable temperature may be different for each of the DC/DC converters 92, 94, . . . and the LDOs 96, . . . , the overcurrent threshold value and the overheat threshold value of the overcurrent/overheat detectors 98, 100, 102, . . . may be different. The detection result is hardware failure information indicating what type of hardware failure has occurred in which block. Failure includes overcurrent or overheat.

The control unit 54 includes a memory 88 and an I2C I/F 90 in addition to the control logic 86. The control logic 86 may be a processor or an SoC. The control unit 54 may be a single IC, but may be discrete elements. The I2C I/F 90 is connected to the controller 22 and an analyzer 112 via an I2C bus line.

The control logic 86 writes the hardware failure information supplied from the overcurrent/overheat detectors 72, 74, 76, 78, 98, 100, and 102 into the memory 88. Like the SFROM 28, the memory 88 is a nonvolatile programmable memory. The memory 88 may be a flash memory, but it may be a one-time ROM (OTP-PROM) capable of writing once, or an electrically programmable/erasable ROM (EPPROM). When at least one of the overcurrent/overheat detectors 72, 74, 76, 78, 98, 100, and 102 detects overcurrent/overheat, the control logic 86 stops operations of all blocks of the power supply unit 52 and the driving unit 56, that is, the load switches 62 and 64, the step-up circuit 66, the PLP step-up/down circuit 68, the DC/DC converters 92, 94, . . . , and the LDOs 96, . . . , and stops operation of the power supply circuit 30.

The hardware failure information stored in the memory 88 can be read via I2C interface (I/F) 90 by the analyzer 112. The I2C terminal is not connected to the connector 23 (see FIG. 2) of the SSD 20 so that the general user cannot access the hardware failure information in the memory. When the hardware failure information stored in the memory 88 is to be read, a dongle is connected to a check land formed on I2C bus line formed on the substrate 12 of the SSD 20. The hardware failure information read from the memory 88 via the dongle is transferred to the analyzer 112. Note that it is impossible for the controller 22 to read the hardware failure information from the memory 88.

The control logic 86 is connected to the controller 22 via the I2C I/F 90. The I2C I/F 90 receives a voltage control signal transmitted from the controller 22 and supplies the received voltage control signal to the control logic 86. The voltage control signal is supplied to the load switches 62 and 64, the step-up circuit 66, the PLP step-up/down circuit 68 in the power supply unit 52, the DC/DC converters 92, 94, . . . and the LDOs 96, . . . in the driving unit 56. ON/OFF of the load switches 62 and 64, and output voltages and output currents of the step-up circuit 66, the PLP step-up/down circuit 68, the DC/DC converters 92, 94, . . . , and the LDOs 96, . . . are controlled.

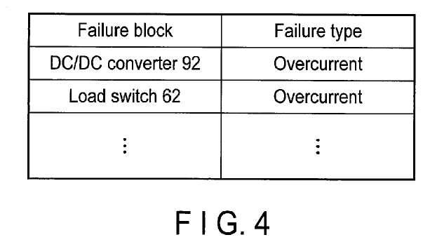

FIG. 4 is a diagram showing an example of the hardware failure information stored in the memory 88. The hardware failure information includes a failure block and a failure type. When a hardware failure occurs, the SSD 20 is collected by the manufacturer. The collected SSD 20 is often discarded and is rarely repaired and reused. Therefore, it suffices that only one item of hardware failure information can be stored in the memory 88. However, in some cases, the SSD 20 may be activated again after a shutdown due to a hardware failure, and the hardware failure may be detected a plurality of times. For example, when the operation of the DC/DC converter 92 is stopped due to overcurrent/overheat and the hardware failure information of the DC/DC converter 92 is written into the memory 88, the operations of other blocks (the load switches 62 and 64, the step-up circuit 66, the PLP step-up/down circuit 68, the DC/DC converter 94, and the LDO 96) are also all stopped and the SSD 20 is shut down. Thereafter, the external power supply 8 may be turned off and then turned on again. In this case, when the SSD 20 is activated and the condition that the DC/DC converter 92 has become overcurrent/overheat does not change (or is maintained), the DC/DC converter 92 stops the operation again and is shut down again. Recording this several shut downs in the memory 88 is useful for failure analysis.

To deal with this, the memory area of the memory 88 is divided into a plurality of areas based on an address/bank, and a plurality of items of hardware failure information can be written into chronological order (including sequentially at different timings, etc.). The way of dividing the memory area is arbitrary. FIG. 4 shows that the overcurrent is occurred in the DC/DC converter 92 and then the overcurrent is occurred in the load switch 62.

When a plurality of hardware failures are detected, a plurality of items of hardware failure information may be sequentially recorded in consecutive areas of the memory 88. If the number of divided areas is small and there is no area to store new hardware failure information when a hardware failure is detected, the hardware failure information may be overwritten on the recording area of the oldest hardware failure information. In some cases, hardware failures are detected simultaneously in a plurality of blocks, but at this time, all of the plurality of items of hardware failure information may be written into the memory 88 or only some items of hardware failure information may be written. The way of determining the hardware failure information to be written into the memory 88 may depend on the priority of the block. Priority is set in advance to each block of the power supply unit 52 and the drive unit 56, only the hardware failure information detected in block with the high priority may be written into the memory 88, and the hardware failure information detected in block with the low priority may not be written into the memory 88.

[Recording of Failure Information]

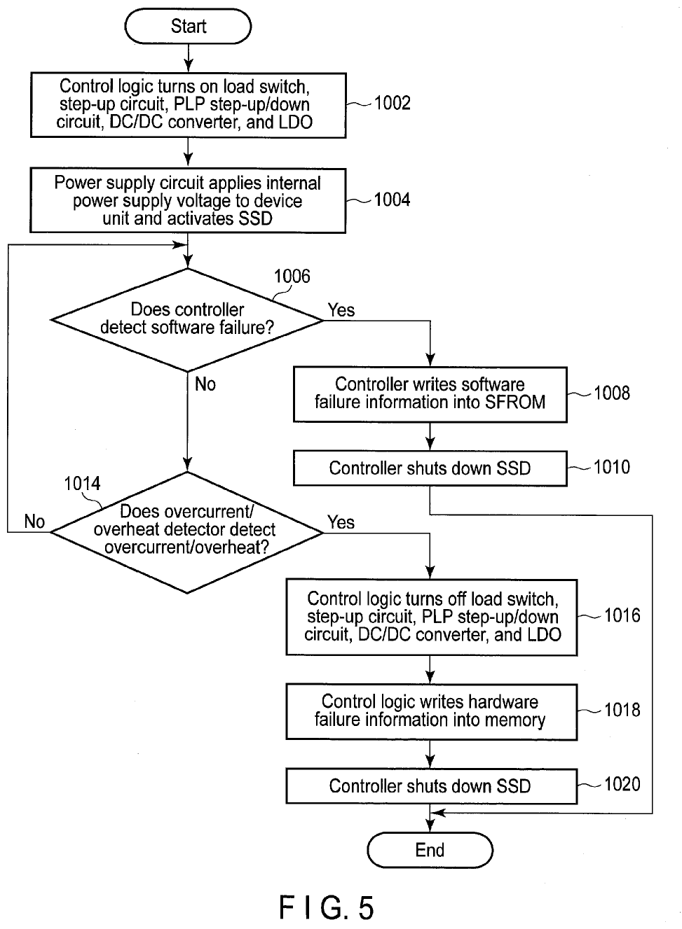

FIG. 5 is a flowchart showing an example of a procedure for recording hardware failure information. Although the hardware failure information may be recorded during use of the SSD 20 after shipment, it may be stored during the test before shipment of the SSD 20.

In block 1002, the control logic 86 turns on the load switches 62 and 64, the step-up circuit 66, the PLP step-up/down circuit 68, the DC/DC converters 92, 94, . . . and the LDOs 96, . . . . As a result, the power supply unit 52 and the driving unit 56 start operations. In block 1004, the power supply circuit 30 generates the internal power supply voltages V1, V2, V3, from the external power supply (12V, 5V), and applies the internal power supply voltages V1, V2, V3, . . . to the device unit 58 and activates the SSD 20.

When the SSD 20 is activated, the controller 22 writes data into the flash memory 24 or reads data from the flash memory 24 according to a command from the host 10. At this time, the controller 22 buffers the data in the DRAM 26. The controller 22 sends a voltage control signal corresponding to the measured temperature of the temperature sensor 31 to the control unit 54 so that the voltage generated by the power supply circuit 30 is adjusted according to the temperature of the SSD 20. During the operation of the SSD 20, if a software failure occurs, the communication between the controller 22 and the flash memory 24, the DRAM 26, the temperature sensor 31, or the like fails, and the SSD 20 cannot operate normally. Alternatively, if a software failure occurs, the controller 22 accesses the error area of the flash memory 24 or the DRAM 26, and the SSD 20 cannot operate normally.

Therefore, in block 1006, it is determined whether the controller 22 detects the software failure as described above. If the controller 22 does not detect the software failure (No in block 1006), then in block 1014, the control logic 86 determines whether or not at least one of the overcurrent/overheat detectors 72, 74, 76, 78, 98, 100, 102, . . . has detected overcurrent/overheat. When all of the overcurrent/overheat detectors 72, 74, 76, 78, 98, 100, 102, . . . do not detect overcurrent/overheat (No in block 1014), the flow returns to the process of block 1006, and the detection of the software failure is repeated.

If the controller 22 detects the software failure (Yes in block 1006), the controller 22 writes software failure information into the SFROM 28 in block 1008. Thereafter, in block 1010, the controller 22 saves the unwritten data buffered in the DRAM 26 to the flash memory 24, and shuts down the SSD 20 to complete the process. Depending on the degree of software failure, the SSD 20 may not be shut down normally.

In the block 1014, when at least one of the overcurrent/overheat detectors 72, 74, 76, 78, 98, 100, 102, . . . detects overcurrent/overheat (Yes in block 1014), the control logic 86 turns off all of the load switches 62 and 64, the step-up circuit 66, the PLP step-up/down circuit 68, the DC/DC converters 92, 94, . . . , and the LDOs 96, . . . in block 1016. As a result, the output of the voltage signals of 12V from the load switch 62 and the step-up circuit 66 is stopped, but a voltage signal of 12V is output from the PLP step-up/down circuit 68 and the internal power supply voltages V1, V2, V3, . . . are applied to the device unit 58 for a particular period during which the electric charge charged in the PLP capacitor 80 is discharged. In this particular period, in block 1018, the control logic 86 writes, into the memory 88, the hardware failure information based on the output of at least one of the overcurrent/overheat detectors 72, 74, 76, 78, 98, 100, 102, . . . that detects overcurrent/overheat. Thereafter, in block 1020, the controller 22 saves the unwritten data buffered in the DRAM 26 to the flash memory 24, and shuts down the SSD 20 to complete the process. Writing the hardware failure information into the memory 88 may be performed during shutdown or before shutdown of the SSD 20.

If the product before shipment is being tested, after the shutdown, the hardware failure information is read from the memory 88, the software failure information is read from the SFROM 28, and the failure analysis is performed. If the product is in use by the user, the SSD 20 is collected by, for example, a manufacturer after shutdown, and failure analysis is performed based on the hardware failure information stored in the memory 88 and the software failure information stored in the SFROM 28.

### Effect of Embodiment

When a failure such as overcurrent/overheat occurs in the devices 22, 24, 26, 28, 31 or the like included in the SSD 20 which is an example of an electronic device, a block corresponding to a failure device among a plurality of blocks which generate the internal power supply voltages included in the driving unit 56 included in the power supply circuit 30 also falls into a failure state, such as overcurrent/overheat. When a particular block falls into a failure state, such as overcurrent/overheat, another block connected to the block may also fall into a failure state, such as overcurrent/overheat. When the overcurrent/overheat of the block is detected by the overcurrent/overheat detectors 72, 74, 76, 78, 98, 100, 102, . . . the operation of the power supply circuit 30 is stopped and the SSD 20 is shut down. Since the system power supply VSYS from the power supply unit 52 is supplied to the control unit 54 even when the operation of the power supply circuit 30 is stopped, the control logic 86 can write hardware failure information of a block in which overcurrent/overheat is detected by the overcurrent/overheat detectors 72, 74, 76, 78, 98, 100, and 102 into the memory 88 provided in the power supply circuit 30. Therefore, even if a device included in the SSD 20, for example, the controller 22 fails, the hardware failure information can be written into the memory 88.

Even in the case where the controller 22 is normal but the power supply circuit 30 fails and cannot supply the internal power supply voltages V1, V2, V3, . . . , it is also possible to write the hardware failure information into the memory 88 by the control logic 86 to which the system power supply VSYS is supplied.

In this manner, since the hardware failure information of the power supply circuit 30 is written into the memory 88 regardless of the controller 22 of the SSD 20, hardware failure information can be recorded in a nonvolatile manner irrespective of the state of the controller 22 (presence or absence of failure). The information stored in the memory 88 is read into the analyzer 112 via the I2C bus line, and the failure analysis is easily executed.

The embodiment is applicable not only to the power supply device of the SSD but also to the power supply device of a hard disk drive (HDD). In the HDD, electric power at the time of power shutdown can be generated by counter electromotive force (force to stop rotation) of the magnetic disk, so the PLP step-up/down circuit 68 and the PLP capacitor 80 are unnecessary.

It is to be noted that the present invention is not limited to the above embodiment as it is, and constituent elements can be modified and embodied in the implementation stage within a range not departing from the gist thereof. In addition, various inventions can be formed by appropriately combining a plurality of constituent elements disclosed in the above embodiment. For example, some constituent elements may be deleted from all the constituent elements shown in the embodiment. Further, constituent elements over different embodiments may be appropriately combined.

What is claimed is:

1. A power supply device comprising:
a power supply circuit comprising a plurality of circuit blocks and configured to generate a plurality of power supply voltages based on an external power supply;
a plurality of detectors that detect failures of the circuit blocks;
a nonvolatile memory; and
a controller that stops an operation of the power supply circuit when any of the detectors detects the failure of any of the circuit blocks, and writes failure information of the power supply circuit into the nonvolatile memory, wherein
the failure information comprises information indicating a type of the failure which has occurred and a circuit block among the circuit blocks in which the failure has occurred.

2. The power supply device according to claim 1, wherein
each of the detectors comprises an overcurrent detector that detects that a current flowing through the circuit block is equal to or more than a threshold value, and
the failure information comprises information indicating a circuit block among the circuit blocks, which is in an overcurrent state.

3. The power supply device according to claim 1, wherein
each the detectors comprises an overheat detector that detects that a temperature of the circuit block is equal to or higher than a threshold value, and
the failure information comprises information indicating a circuit block among the circuit blocks, which is in an overheat state.

4. The power supply device according to claim 1, wherein the circuit blocks comprise:
a first load switch that outputs a first voltage signal from the external power supply and stops output of the first voltage signal upon detection of failure;
a second load switch that outputs a second voltage signal from the external power supply and stops output of the second voltage signal upon detection of failure;
a step-up circuit that steps up an output of the second load switch and outputs a step-up signal having the same voltage as the first voltage signal;
a step-up/down circuit that steps up an output of the first load switch and an output of the step-up circuit to charge a capacitor with a step-up voltage or steps down a charging voltage of the capacitor and outputs a step-down signal having the same voltage as the first voltage signal; and
a plurality of converters that generate the power supply voltages based on the output of the first load switch, the step-up signal of the step-up circuit, and the step-down signal of the step-up/down circuit.

5. The power supply device according to claim 1, wherein the controller is able to be connected to an electronic device via a serial communication interface, and the failure information in the nonvolatile memory can be read by the electronic device via the serial communication interface.

6. The power supply device according to claim 1, wherein
the nonvolatile memory comprises a nonvolatile programmable memory; and
the nonvolatile programmable memory comprises a flash memory, a one-time read-only memory capable of writing once, or an electrically programmable/erasable read-only memory.

7. The power supply device according to claim 1, wherein
the controller writes the failure information into the nonvolatile memory when detecting an abnormality of a particular circuit block among the circuit blocks, and
the controller does not write the failure information into the nonvolatile memory when detecting an abnormality of a circuit block among the blocks other than the particular circuit block.

8. The power supply device according to claim 1, wherein
the nonvolatile memory comprises a plurality of areas into which a plurality of items of the failure information detected at different timings can be written, and
the controller overwrites new failure information with old failure information when the items of the failure information have already been written into the areas.

9. A power supply control method of a power supply circuit comprising a plurality of circuit blocks and configured to generate a plurality of power supply voltages based on an external power supply, the method comprising:
stopping an operation of the power supply circuit when a failure of the power supply circuit is detected; and
writing failure information of the power supply circuit into a nonvolatile memory, wherein
the failure information comprises information indicating a type of the failure which has occurred and a circuit block among the circuit blocks in which the failure has occurred.

10. The power supply control method according to claim 9, wherein
the failure of the power supply circuit comprises an overcurrent wherein a current flowing through the circuit block is equal to or more than a threshold value, and
the failure information comprises information indicating a circuit block among the circuit blocks, which is in an overcurrent state.

11. The power supply control method according to claim 9, wherein
the failure of the power supply circuit comprises an overheat wherein a temperature of the circuit block is equal to or higher than a threshold value, and
the failure information comprises information indicating a circuit block among the circuit blocks, which is in an overheat state.

12. The power supply control method according to claim 9, wherein the circuit blocks comprise:
a first load switch that outputs a first voltage signal from the external power supply and stops output of the first voltage signal upon detection of failure;
a second load switch that outputs a second voltage signal from the external power supply and stops output of the second voltage signal upon detection of failure;
a step-up circuit that steps up an output of the second load switch and outputs a step-up signal having the same voltage as the first voltage signal;
a step-up/down circuit that steps up an output of the first load switch and an output of the step-up circuit to charge a capacitor with a step-up voltage or steps down a charging voltage of the capacitor and outputs a step-down signal having the same voltage as the first voltage signal; and
a plurality of converters that generate the power supply voltages based on the output of the first load switch, the step-up signal of the step-up circuit, and the step-down signal of the step-up/down circuit.

13. A storage device comprising:
a nonvolatile memory;
a controller configured to control a read operation of the nonvolatile memory or a write operation of the nonvolatile memory; and
a power supply circuit comprising a plurality of circuit blocks and configured to generate a plurality of power supply voltages based on an external power supply, wherein
the power supply circuit comprises a plurality of detectors that detect failures of the circuit blocks,
the controller stops an operation of the power supply circuit when any of the detectors detects the failure of any of the circuit blocks, and writes failure information of the power supply circuit into the nonvolatile memory, and
the failure information comprises information indicating a type of the failure which has occurred and a circuit block among the circuit blocks in which the failure has occurred.

14. The storage device according to claim 13, wherein
each of the detectors comprises an overcurrent detector that detects that a current flowing through the circuit block is equal to or more than a threshold value, and
the failure information comprises information indicating a circuit block among the circuit blocks, which is in an overcurrent state.

15. The storage device according to claim 13, wherein
each the detectors comprises an overheat detector that detects that a temperature of the circuit block is equal to or higher than a threshold value, and
the failure information comprises information indicating a circuit block among the circuit blocks, which is in an overheat state.

16. The storage device according to claim 13, wherein the circuit blocks comprise:
a first load switch that outputs a first voltage signal from the external power supply and stops output of the first voltage signal upon detection of failure;
a second load switch that outputs a second voltage signal from the external power supply and stops output of the second voltage signal upon detection of failure;
a step-up circuit that steps up an output of the second load switch and outputs a step-up signal having the same voltage as the first voltage signal;
a step-up/down circuit that steps up an output of the first load switch and an output of the step-up circuit to charge a capacitor with a step-up voltage or steps down a charging voltage of the capacitor and outputs a step-down signal having the same voltage as the first voltage signal; and
a plurality of converters that generate the power supply voltages based on the output of the first load switch, the step-up signal of the step-up circuit, and the step-down signal of the step-up/down circuit.

17. The storage device according to claim 13, wherein the controller is able to be connected to an electronic device via a serial communication interface, and the failure information in the nonvolatile memory can be read by the electronic device via the serial communication interface.

18. The storage device according to claim 13, wherein
the nonvolatile memory comprises a nonvolatile programmable memory; and
the nonvolatile programmable memory comprises a flash memory, a one-time read-only memory capable of writing once, or an electrically programmable/erasable read-only memory.

19. The storage device according to claim 13, wherein
the controller writes the failure information into the nonvolatile memory when detecting an abnormality of a particular circuit block among the circuit blocks, and
the controller does not write the failure information into the nonvolatile memory when detecting an abnormality of a circuit block among the blocks other than the particular circuit block.

20. The storage device according to claim 13, wherein
the nonvolatile memory comprises a plurality of areas into which a plurality of items of the failure information detected at different timings can be written, and
the controller overwrites new failure information with old failure information when the items of the failure information have already been written into the areas.
